(19) United States
(12) Patent Application Publication
(10) Pub. No.: US 2024/0387517 A1
(43) Pub. Date: Nov. 21, 2024

(54) SEMICONDUCTOR DEVICES AND METHODS OF MANUFACTURE

(71) Applicant: Taiwan Semiconductor Manufacturing Co., Ltd., Hsinchu (TW)

(72) Inventors: Po-Chuan Wang, Taipei (TW); Guan-Xuan Chen, Taoyuan (TW); Chia-Yang Hung, Kaohsiung (TW); Sheng-Liang Pan, Hsinchu (TW); Huan-Just Lin, Hsinchu (TW)

(21) Appl. No.: 18/786,525

(22) Filed: Jul. 28, 2024

Related U.S. Application Data
(62) Division of application No. 17/652,398, filed on Feb. 24, 2022.

(51) Int. Cl. H01L 27/06; H01L 21/265; H01L 29/66; H01L 29/78

(52) U.S. Cl. CPC H01L 27/0629; H01L 21/26513; H01L 28/20; H01L 29/66545; H01L 29/66795; H01L 29/7851

(57) ABSTRACT

Semiconductor devices and methods of manufacturing the semiconductor devices are described herein. A method includes forming a gate electrode, a gate electrode contact layer over the gate electrode, forming a dielectric layer over the gate electrode contact layer, and performing an etch through the dielectric layer, the etch forming an opening that exposes the gate electrode contact layer. The method further includes performing a post-etch treatment on the opening formed by the etch process by exposing the opening to a plasma. The method further includes forming gate electrode contacts in the openings after the post-etch treatment by a bottom-up deposition process.

### PRIORITY CLAIM AND CROSS-REFERENCE

This application is a divisional of U.S. patent application Ser. No. 17/652,398 filed on Feb. 24, 2022, which application is hereby incorporated herein by reference in its entirety.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates the formation of fins, isolation regions, dummy dielectric and a dummy gate, in accordance with some embodiments.

FIG. 2 illustrates the formation of source/drain regions, gate spacers and dummy gate masks, in accordance with some embodiments.

FIG. 3 illustrates the formation of a first interlayer dielectric (ILD), in accordance with some embodiments.

FIG. 4 illustrates the replacement of the dummy dielectric and the dummy gate with gate dielectric layers and gate electrodes, in accordance with some embodiments.

FIG. 5 illustrates the formation of a gate contact layer and a gate mask, in accordance with some embodiments.

FIG. 6 illustrates the formation of silicide regions and source/drain plugs, in accordance with some embodiments.

FIG. 7 illustrates the formation of a first etch stop layer, a contact etch stop layer, a second interlayer dielectric, and source/drain contacts in accordance with some embodiments.

FIG. 8 illustrates the formation of a third inter dielectric layer, and an etching process in the formation of openings for gate contacts, in accordance with some embodiments.

FIG. 9 illustrates the continuation of the etching process in the formation of openings for gate contacts of a first semiconductor device, and the formation of etch by-products in accordance with some embodiments.

FIG. 10 illustrates a post-etch cleaning step, in accordance with some embodiments.

FIG. 11 illustrates the formation of gate contacts and alternatively butted contacts, in accordance with some embodiments.

FIGS. 12A-12C illustrate various results from the bottom-up deposition process deriving from the post-etch treatment parameters, in accordance with some embodiments.

FIG. 13 illustrates the formation of a barrier layer over exposed contacts and a rigid plug, in accordance with some embodiments.

FIG. 14 illustrates a planarization of the semiconductor structure exposing conductive contacts in a planar surface, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

This disclosure relates to a semiconductor device and its manufacturing method, and more particularly to a semiconductor device comprising a contact to a source/drain region. Embodiments discussed herein, however, are intended to be illustrative embodiments, and are not intended to limit the embodiments to those specifically discussed. For example, embodiments disclosed herein are directed towards the formation of a plurality of fin-type field effects transistors (finFETs) within a wafer, but the ideas presented may be implemented in a wide variety of devices.

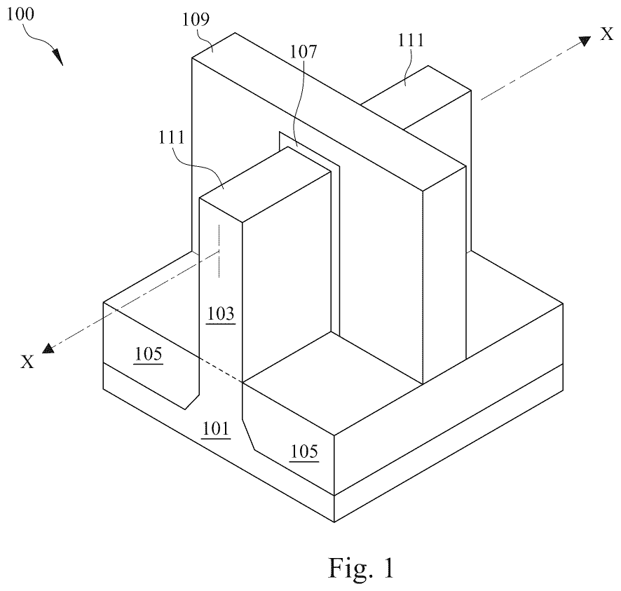

FIG. 1 illustrates a three-dimensional view of an intermediate structure 100 formed during the formation of a finFET device, in accordance with some embodiments. The intermediate structure 100 comprises a fin 103 on a substrate 101 (e.g., a semiconductor substrate). Isolation regions 105 are disposed in the substrate 101, and the fin 103 protrudes above and from between neighboring isolation regions 105. Although the isolation regions 105 are described and/or illustrated as being separate from the substrate 101, as used herein the term “substrate” may be used to refer to just a semiconductor substrate or a semiconductor substrate inclusive of the isolation regions 105. Additionally, although the fin 103 is illustrated as a single, continuous material as the substrate 101, the fin 103 and/or the substrate 101 may comprise a single material or a plurality of materials. In this context, the fin 103 refers to the portion extending between the neighboring isolation regions 105.

A dummy gate dielectric layer 107 is along sidewalls and over a top surface of the fin 103, and a dummy gate electrode 109 is over dummy gate dielectric layer 107. Source/drain regions 111 (once regrown) are disposed in opposite sides of the fin 103 with respect to dummy gate dielectric layer 107 and dummy gate electrode 109. FIG. 1 further illustrates reference cross-section X-X that is used in later figures. Cross-section X-X is perpendicular to a longitudinal axis of the dummy gate electrode 109 of the finFET and extends through the source/drain regions 111 on opposing sides of the dummy gate electrode 109 of the finFET in a direction parallel to, for example, a current flow between the source/drain regions 111 of the finFET. Subsequent figures refer to this reference cross-section X-X for clarity. However, FIG. 1 only illustrates one of the fins 103 formed from the substrate 101, any number of the fins 103 may be utilized and multiple fins 103 and associated structures are illustrated in subsequent figures.

Some embodiments discussed herein are discussed in the context of finFETs formed using a gate-last process. In other embodiments, a gate-first process may be used. Also, some embodiments contemplate aspects used in planar devices, such as planar FETs, nanostructure (e.g., nanosheet, nanowire, gate-all-around, or the like) field effect transistors (NSFETs), or the like.

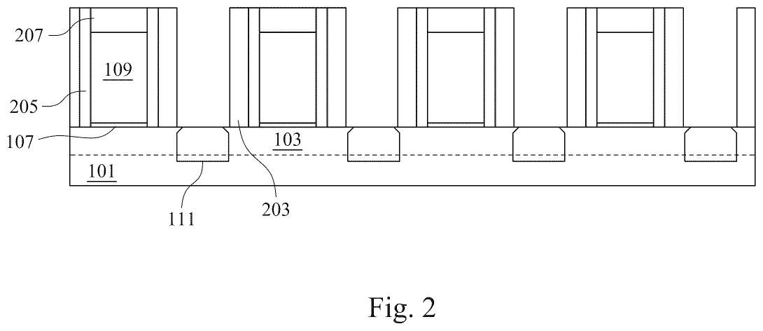

With reference to FIGS. 1 and 2, these figures illustrate some initial steps in the formation of finFETs including patterning a plurality of the fins 103 from the substrate 101. The substrate 101 may be a silicon substrate, although other substrates, such as semiconductor-on-insulator (SOI), strained SOI, and silicon germanium on insulator, could be used. The substrate 101 may be a p-type semiconductor, although in other embodiments, it could be an n-type semiconductor. The fins 103 may be patterned by forming trenches using any suitable method. For example, the fins 103 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 103.

However, as one of ordinary skill in the art will recognize, the processes and materials described above to form the series of fins 103 are merely example processes, and are not meant to be the only embodiments. Rather, any suitable process through which the fins 103 may be formed may be utilized and any suitable process, including any number of masking and removal steps may be used. Once formed, these fins 103 may be used, as discussed below, to form the channel regions and source/drain regions 111 of a plurality of finFET transistors. After the fins 103 have been formed within the substrate 101, the isolation regions 105, such as shallow trench isolation (STI) regions may be formed to isolate the fins 103 from other regions within the substrate 101. As such, the trenches may be filled with a dielectric material and the dielectric material may be recessed within the first trenches to form the isolation regions 105. The dielectric material may be an oxide material, a high-density plasma (HDP) oxide, or the like. The dielectric material may be formed, after an optional cleaning and lining of the trenches, using either a chemical vapor deposition (CVD) method, a high density plasma CVD method, or any other suitable method of formation may be used.

The trenches may be filled by overfilling the trenches and the substrate 101 with the dielectric material and then removing the excess material outside of the trenches and the fins 103 through a suitable process such as chemical mechanical polishing (CMP), an etch, a combination of these, or the like. In an embodiment, the removal process removes any dielectric material that is located over the fins 103 as well, so that the removal of the dielectric material will expose the surface of the fins 103 to further processing steps.

Once the trenches have been filled with the dielectric material, the dielectric material may then be recessed away from the surface of the fins 103. The recessing may be performed to expose at least a portion of the sidewalls of the fins 103 adjacent to the top surface of the fins 103. The dielectric material may be recessed using a wet etch by dipping the top surface of the fins 103 into an etchant such as HF, although other etchants, such as H₂, and other methods, such as a reactive ion etch, a dry etch with etchants such as NH₃/NF₃, chemical oxide removal, or dry chemical clean may be used. The dielectric material may be recessed to a distance from the surface of the fins 103 of between about 50 Å and about 500 Å, such as about 400 Å. Additionally, the recessing may also remove any leftover dielectric material located over the fins 103 to ensure that the fins 103 are exposed for further processing.

The steps described above may be only part of the overall process flow used to fill and recess the dielectric material. For example, lining steps, cleaning steps, annealing steps, gap filling steps, combinations of these, and the like may also be utilized to form and fill the trenches with the dielectric material. All of the potential process steps are fully intended to be included within the scope of the present embodiment.

After the isolation regions 105 have been formed, appropriate wells (not shown) may be formed in the fins 103 and/or the substrate 101. In some embodiments, different well types are formed within different n-type regions and the p-type regions of the fins 103 and/or the substrate 101. As such, the different implant steps for the n-type regions and the p-type regions may be achieved using a photoresist and/or other masks (not shown). For example, a photoresist may be formed over the fins 103 and the isolation regions 105 in the n-type regions. The photoresist is patterned to expose the p-type regions of the substrate 101. The photoresist can be formed by using a spin-on technique and can be patterned using acceptable photolithography techniques. Once the photoresist is patterned, an n-type impurity implant is performed in the p-type regions, and the photoresist may act as a mask to substantially prevent n-type impurities from being implanted into the n-type regions. The n-type impurities may be phosphorus, arsenic, antimony, or the like implanted in the region to a concentration of equal to or less than 10¹⁸ cm⁻³, such as between about 10¹⁶ cm⁻³ and about 10¹⁸ cm⁻³. After the implant, the photoresist is removed, such as by an acceptable ashing process.

Following the implanting of the p-type regions, a photoresist can be formed over the fins 103 and the isolation regions 105 in the p-type region and then patterned to expose the n-type regions of the substrate 101 to initiate an implanting of the n-type regions. Once the photoresist is patterned, a p-type impurity implant may be performed in the n-type regions using the photoresist as a mask to substantially prevent p-type impurities from being implanted into the p-type regions. The p-type impurities may be boron, boron fluoride, indium, or the like implanted in the region to a concentration of equal to or less than 10¹⁸ cm⁻³, such as between about 10¹⁶ cm⁻³ and about 10¹⁸ cm⁻³. After the implant, the photoresist may be removed, such as by an acceptable ashing process.

After the implants of the n-type regions and the p-type regions, an anneal process may be performed to repair implant damage and to activate the p-type and/or n-type impurities that were implanted. In some embodiments in which the fins 103 or a portion of the fins 103 are grown, the grown materials of epitaxial of the fins 103 may be in situ doped during growth, which may obviate the implantations, although in situ and implantation doping may be used together.

Once the wells have been formed in the fins 103 and/or the substrate 101, a dummy gate dielectric layer 107 and a dummy gate electrode 109 may be formed over each of the fins 103. Initially, a dummy gate dielectric (or interface oxide) layer and a dummy gate electrode layer over the dummy gate dielectric layer may be formed over each of the fins 103. In an embodiment the dummy gate dielectric layer may be formed by thermal oxidation, chemical vapor deposition, sputtering, or any other methods known and used in the art for forming a gate dielectric layer. Depending on the technique of formation, the dummy gate dielectric layer thickness on the top of the fins 103 may be different from the dummy gate dielectric layer thickness on the sidewall of the fins 103.

The dummy gate dielectric layer may comprise a material such as silicon dioxide or silicon oxynitride with a thickness of between about 3 Å and about 100 Å, such as about 10 Å. The dummy gate dielectric layer may be formed from a high permittivity (high-k) material (e.g., with a relative permittivity greater than about 5) such as lanthanum oxide (La₂O₃), aluminum oxide (Al₂O₃), hafnium oxide (HfO₂), hafnium oxynitride (HfON), or zirconium oxide (ZrO₂), or combinations thereof, with an equivalent oxide thickness of between about 0.5 Å and about 100 Å, such as about 10 Å or less. Additionally, any combination of silicon dioxide, silicon oxynitride, and/or high-k materials may also be used for the dummy gate dielectric layer.

The dummy gate electrode layer may comprise a conductive material and may be selected from a group comprising of polysilicon (e.g., a dummy polysilicon (DPO)), W, Al, Cu, AlCu, W, Ti, TiAlN, TaC, TaCN, TaSiN, Mn, Zr, TiN, Ta, TaN, Co, Ni, combinations of these, or the like. The dummy gate electrode layer may be deposited by chemical vapor deposition (CVD), sputter deposition, or other suitable techniques for depositing conductive materials. The thickness of the dummy gate electrode layer may be between about 5 Å and about 200 Å. The top surface of the dummy gate electrode layer may have a non-planar top surface, and may be planarized prior to patterning of the dummy gate electrode layer or performing the gate etching process. Ions may or may not be introduced into the dummy gate electrode layer at this point. Ions may be introduced, for example, by ion implantation techniques.

Once formed, the dummy gate dielectric layer and the dummy gate electrode layer may be patterned to form a series of dummy gate dielectric layers 107 and dummy gate electrodes 109 over the fins 103. The dummy gate electrodes 109 may be formed by depositing and patterning a hard mask 207 on the dummy gate electrode layer using, for example, any suitable deposition and photolithography techniques. The hard mask 207 may incorporate any suitable masking and sacrificial materials, such as (but not limited to) silicon oxide, silicon oxynitride, SiCON, SiC, SiOC, and/or silicon nitride and may be deposited to a thickness of between about 5 Å and about 200 Å. The dummy gate electrode layer and the dummy gate dielectric layer may be etched using a dry etching process to form the dummy gate electrodes 109 and the dummy gate dielectric layer 107. As such, the dummy gate electrodes 109 define multiple channel regions located on each side of the fins 103 beneath the dummy gate dielectric layer 107.

Turning to FIG. 2, which illustrates additional ones of the dummy gate dielectric layers 107 and the dummy gate electrodes 109 over the fin 103, wherein the fins 103 may be in the same or different regions of the substrate 101, once the dummy gate electrodes 109 have been patterned, gate spacers 203 may be formed on opposing sides of the dummy gate electrodes 109, according to some embodiments. The gate spacers 203 are formed, for example, by blanket depositing a stack of spacer layers on the previously formed structure. The spacer layer may comprise a different material with different etch characteristics or the same material as the dielectric material within the isolation regions 105. The insulating material of the gate spacers 203 may be silicon oxide, silicon nitride, silicon oxynitride, silicon carbonitride, a combination thereof, or the like. The gate spacers 203 may then be patterned, such as by one or more etches to remove the spacer layer from the horizontal surfaces of the structure, to form the gate spacers 203.

According to some embodiments, optional gate seal spacers 205 may be formed prior to formation of the gate spacers 203. The optional gate seal spacers 205 can be formed by blanket deposition on exposed surfaces of the dummy gate electrodes 109, the masks, and/or the fins 103. The optional gate seal spacers 205 may comprise SiCON, SiN, oxynitride, SiC, SiON, SiOC, oxide, or the like and may be formed by any suitable methods to form such a layer, such as chemical vapor deposition (CVD), plasma enhanced chemical vapor deposition (PECVD), sputter, and any other suitable methods. A thermal oxidation or a deposition followed by an anisotropic etch may form the optional gate seal spacers 205.

After the formation of the gate spacers 203, implants for lightly doped source/drain (LDD) regions (not explicitly illustrated) may be performed. In the embodiments with different device types, similar to the implants discussed above, a mask, such as a photoresist, may be formed over regions of the structure to be protected and appropriate type (e.g., p-type or n-type) impurities may be implanted into the exposed fins 103 in the unmasked region. The mask may then be removed. Subsequent masking and implantation processes may be performed to appropriately dope different regions of the structure based on desired devices being formed. The lightly doped source/drain regions may have a concentration of impurities of from about 10¹⁵ cm⁻³ to about 10¹⁹ cm⁻³. An anneal process may be used to repair implant damage and to activate the implanted impurities.

It is noted that the above disclosure generally describes a process of forming spacers and LDD regions. Other processes and sequences may be used. For example, fewer or additional spacers may be utilized, a different sequence of steps may be utilized (e.g., the optional gate seal spacers 205 may not be etched prior to forming the gate spacers 203, yielding “L-shaped” gate seal spacers), spacers may be formed and removed, and/or the like.

FIG. 2 additionally illustrates, beyond the structure illustrated in FIG. 1, that once the gate spacers 203 have been formed, a removal of portions of the fins 103 not protected by the dummy gate electrodes 109 and the gate spacers 203 are removed using a reactive ion etch (RIE) using the dummy gate electrodes 109 and the gate spacers 203 as hard masks, or by using any other suitable removal process. The removal may be continued until the fins 103 are either planar with or below the surface of the isolation regions 105.

Once the portions of the fins 103 have been removed, the source/drain regions 111 are grown through a selective epitaxial (EPI) growth process of the material of the fins 103. In an embodiment wherein the fins 103 comprise silicon and the finFET is a p-type device, the source/drain regions 111 may be grown with a material, such as silicon, silicon germanium, silicon phosphorous, which has a different lattice constant than the channel regions. The epitaxial growth process may use precursors such as silane, dichlorosilane, germane, or the like, and may continue for between about 5 minutes and about 120 minutes, such as about 30 minutes. In other embodiments the source/drain regions 111 may comprise materials such as GaAs, GaP, GaN, InP, InAs, InSb, GaAsP, AlGaN, AlInAs, AlGaAs, GaInAs, GaInP, and/or GaInAsP; or combinations, or the like.

Once the source/drain regions 111 are formed, dopants may be implanted into the source/drain regions 111 by implanting appropriate dopants to complement the dopants in the fins 103. In other embodiments, the dopants may be placed in-situ during the growing of the source/drain regions 111. For example, p-type dopants such as boron, gallium, indium, or the like may be implanted or placed to form a PMOS device. In another embodiment, n-type dopants such as phosphorous, arsenic, antimony, or the like may be implanted or placed to form an NMOS device. In embodiments in which the dopants are implanted, these dopants may be implanted using the dummy gate electrodes 109, the optional gate seal spacers 205 and the gate spacers 203 as masks. However, any other suitable processes, steps, or the like may be used to implant the dopants. For example, a plurality of implantation processes may be performed using various combinations of spacers and liners to form the source/drain regions 111 having a specific shape or characteristic suitable for a particular purpose. Any of these processes may be used to implant the dopants, and the above description is not meant to limit the present embodiments to the steps presented above.

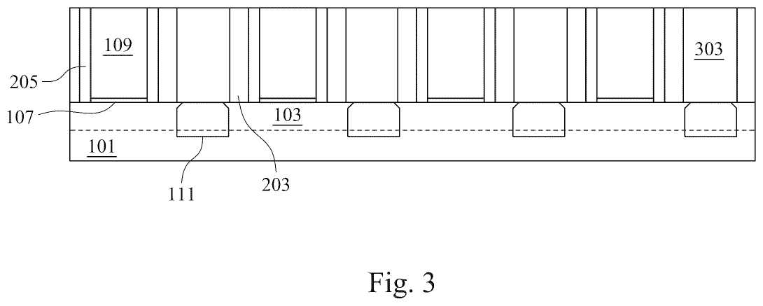

FIG. 3 illustrates a formation of a first interlayer dielectric (ILD) layer 303 over the source/drain regions 111, according to some embodiments. Once the source/drain regions 111 have been formed, the first ILD layer 303 is deposited over the exposed areas of the substrate 101.

According to some embodiments, the first ILD layer 303 may comprise a material such as silicon oxide (SiO₂) or boron phosphorous silicate glass (BPSG), although any suitable dielectrics may be used. The first ILD layer 303 may be formed using a chemical vapor deposition (CVD) process such as plasma enhanced chemical vapor deposition (PECVD), although any other suitable processes, such as low pressure chemical vapor deposition (LPCVD), may also be used.

Once formed, the first ILD layer 303 may be annealed using, e.g., a first annealing process. In an embodiment the first annealing process may be a thermal anneal wherein the substrate 101 and the first ILD layer 303 are heated within, e.g., in a furnace, within an inert atmosphere. The first anneal process may be performed at a temperature of between about 200° C. and about 1000° C., such as about 500° C., and may be continued for a time of between about 60 s and about 360 min, such as about 240 min. Once deposited and annealed, the first ILD layer 303, the gate spacers 203 and the optional gate seal spacers 205 (if present) are planarized to expose the dummy gate electrodes 109 in a planar surface of the first ILD layer 303, wherein the planarization process may also remove the hard mask 207 if still present.

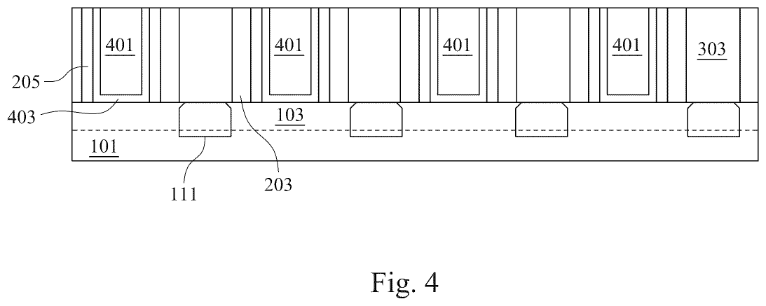

Turning to FIG. 4, once exposed, the dummy gate electrodes 109 and dummy gate dielectric layer 107 are subsequently removed using, e.g., one or more wet etch processes and are replaced with, e.g., high-k gate dielectric layers 403 and gate electrodes 401, including, for example, one or more conductive barrier layers, one or more work function layers, and a conductive fill material. According to some embodiments, the high-k gate dielectric layer 403 includes materials such as HfO₂, ZrO₂, HfZrOₓ, HfSiOₓ, HfSiON, ZrSiOₓ, HfZrSiOₓ, Al₂O₃, HfAlOₓ, HfAlN, ZrAlOₓ, La₂O₃, TiO₂, Yb₂O₃, or the like and may be a single layer or a composite layer that is formed using a deposition process such as atomic layer deposition. However, any suitable materials and any suitable processes may be used to form the high-k gate dielectric layer 403.

According to some embodiments, the one or more diffusion barrier layers and the one or more work-function layer may be formed as a plurality of stacked layers. For example, the barrier layers may be formed as a layer of titanium nitride (TiN) which may (or may not) be doped with silicon. The work-function layer, in the case of a p-type finFET may be formed with a respective gate electrode 401 as a stacked layer including Ti, Al, TiAl, TiAlN, Ta, TaN, TiAlC, TaAlCSi, TaAlC, TiSiN, or the like. In the case of an n-type finFET being formed with a respective gate electrode 401, the work-function layer may be formed with a respective gate electrode 401 as a stacked layer including TiN, TaN, TiAl, W, Ta, Ni, Pt, or the like. After the deposition of the work-function layer(s) in these embodiments, a barrier layer (e.g., another TiN layer) is formed.

According to some embodiments, the conductive fill material may be formed from a material such as tungsten, cobalt, copper, ruthenium, aluminum, or the like. The conductive fill material is deposited over the stacked layers of the high-k gate dielectric layer 403, the one or more conductive barrier layers, the one or more work function layers such that the remaining spaces, between respective gate spacers 203 of a respective gate electrode 401 are filled or over-filled.

Once the layers of the gate electrodes 401 have been deposited and the remaining spaces are completely filled (or over-filled) with the conductive fill material, the materials are then planarized using a chemical mechanical polish (CMP) process. The CMP process may perform a thinning of the materials of the gate electrodes 401, the materials of respective gate spacers 203, optional gate seal spacers 205 (if present), and the first ILD layer 303 until planarized surfaces of the gate electrodes 401 and the gate spacers 203 are exposed in a planar surface of the first ILD layer 303.

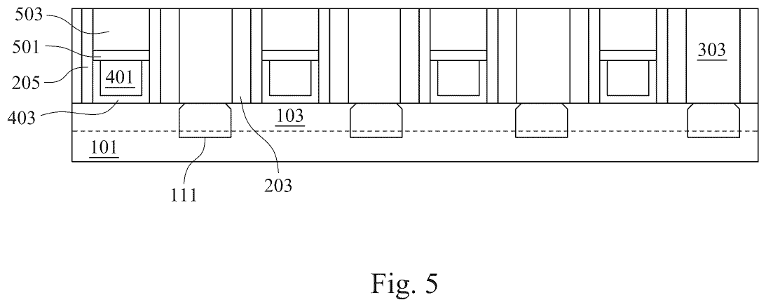

In FIG. 5, the gate electrodes 401 are recessed and a gate contact layer 501 may be deposited over the recessed gate electrodes 401. The gate contact layer 501 may be formed of tungsten, such as fluorine-free tungsten (FFW), which is deposited by a selective deposition process, such as a selective CVD process. However, the gate contact layer 501 may include other conductive materials, such as ruthenium, cobalt, copper, molybdenum, nickel, combinations thereof, or the like and may be deposited using a suitable deposition process (e.g., ALD, CVD, PVD, or the like).

A gate mask 503 comprising one or more layers of dielectric material, such as silicon nitride, silicon oxynitride, or the like, is deposited over the gate contact layer 501 and fills the remainder of the recess. The deposition of the gate mask 503 may be followed by a planarization process to planarize the gate mask 503 and remove any undesired thickness of the dielectric material. The planarization process may be a chemical mechanical polishing process, although any suitable planarization process may be used.

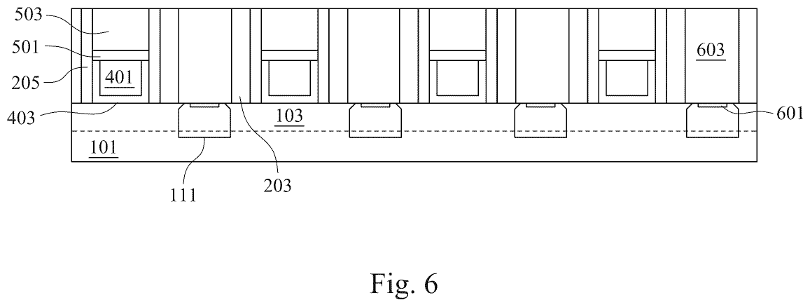

In FIG. 6, silicide regions 601 and source/drain plugs 603 are formed through the first ILD layer 303. The first ILD layer 303 may be etched to form recesses exposing surfaces of the source/drain regions 111. The recesses may be formed by etching using anisotropic etch processes, such as RIE, NBE, or the like. A mask, such as a photoresist, may be formed and patterned over the first ILD layer 303 to mask portions of the first ILD layer 303, the gate spacers 203, and the gate mask 503 from the first etch process and the second etch process. In some embodiments, the etch processes may over-etch, and therefore, the recesses may extend into the source/drain regions 111. Bottom surfaces of the recesses may be level with (e.g., at a same level, or having a same distance from the substrate 101), or lower than (e.g., closer to the substrate 101) top surfaces of the source/drain regions 111.

After the recesses are formed, the silicide regions 601 may be formed. In some embodiments, the silicide regions 601 are formed by first depositing a metal (not separately illustrated) capable of reacting with the semiconductor materials of the underlying source/drain regions 111 (e.g., silicon, silicon germanium, germanium, or the like) to form silicide or germanide regions, such as nickel, cobalt, titanium, tantalum, platinum, tungsten, other noble metals, other refractory metals, rare earth metals or their alloys, over the exposed portions of the source/drain regions 111. A thermal anneal process may then be performed to form the silicide regions 601. Un-reacted portions of the deposited metal are removed by an etch process. Although referred to as silicide regions, the silicide regions 601 may also be germanide regions, silicon germanide regions (e.g., regions comprising silicide and germanide), or the like. In an embodiment, the silicide regions 601 comprise TiSi, and have a thickness ranging from about 2 nm to about 10 nm.

The source/drain plugs 603 are then formed over the silicide regions 601 and filling the recesses. The source/drain plugs 603 may each comprise one or more layers, such as barrier layers, diffusion layers, and fill materials. For example, in some embodiments, the source/drain plugs 603 each include a barrier layer and a conductive material over the barrier layer. The conductive material of each of the source/drain plugs 603 may be electrically coupled to the underlying source/drain regions 111 through the silicide regions 601. The barrier layer may include titanium, titanium nitride, tantalum, tantalum nitride, or the like. The conductive material may be cobalt (Co), ruthenium (Ru), titanium (Ti), tungsten (W), copper (Cu), a copper alloy, silver (Ag), gold (Au), aluminum (Al), nickel (Ni), or the like. After the source/drain plugs 603 are formed, a planarization process, such as a CMP, may be performed to remove excess material from surfaces of the first ILD layer 303 and the gate mask 503.

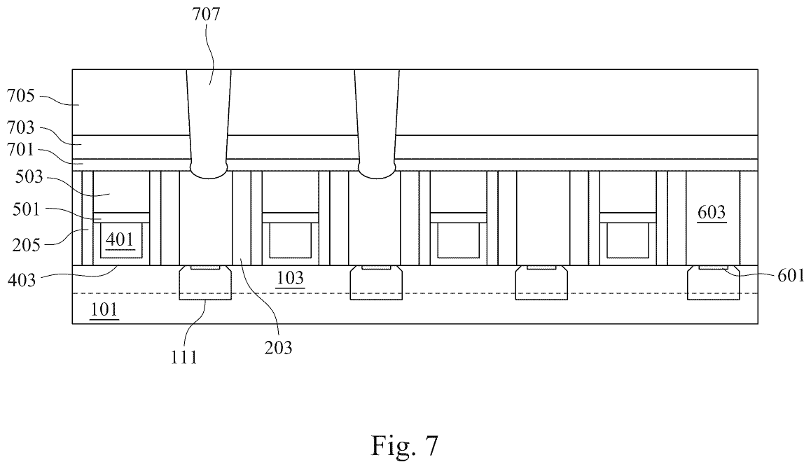

In FIG. 7, a first etch stop layer 701 is formed over exposed surfaces of the gate mask 503, the gate spacers 203 (and the optional gate seal spacers 205) and the source/drain plugs 603, according to some embodiments. In some other embodiments, the first etch stop layer 701 may be formed as an oxide film, e.g., silicon oxide, silicon oxynitride, combinations of these, or the like, using a deposition process such as CVD, PVD, ALD, combinations, or the like. However, any suitable deposition process may be used. As such, a top surface of the first etch stop layer 701 may have a profile the same as or similar to top surfaces of the underlying gate mask 503 and the source/drain plugs 603.

FIG. 7 further illustrates the formation of a contact etch stop layer (CESL) 703 and a second ILD 705 that are formed over the first etch stop layer 701, according to some embodiments. The contact etch stop layer 703 may comprise a dielectric material, such as, silicon nitride, silicon oxide, silicon oxynitride, or the like, having a different etch rate than the material of the overlying second ILD 705 and the underlying first etch stop layer 701 (although the selectivity of the contact etch stop layer 703 to the underlying first etch stop layer 701 may be below 10). The contact etch stop layer 703 may be deposited by a conformal deposition process, such as ALD, CVD, or the like. As such, a top surface of the contact etch stop layer 703 may have a profile the same as or similar to top surfaces of the underlying first etch stop layer 701.

The second ILD 705 may be formed of a dielectric material, and may be deposited by any suitable method, such as CVD, PECVD, or FCVD. Suitable dielectric materials may include PSG, BSG, BPSG, USG, or the like. Other insulation materials formed by any acceptable process may be used. After the second ILD 705 is deposited, a planarization process, such as a CMP, may be performed to planarize a top surface of the second ILD 705.

FIG. 7 further illustrates, according to some embodiments, a formation of first openings (not shown) through the second ILD 705, the contact etch stop layer 703, and the first etch stop layer 701 down to the source/drain plugs 603. Once the second ILD 705 has been formed, the first openings for source/drain contacts 707 can be formed using a series of one or more acceptable photolithography and etching techniques. However, any suitable methods may be utilized.

Because the first etch stop layer 701 is relatively thin (e.g., less than about 5 nm), the first etching process used to form the first openings through the contact etch stop layer 703 can be slowed down (or even stopped) before the first etching process fully punches through the first etch stop layer 701 and mitigates undesired damage. Additionally, after the first etch stop layer 701 has been opened to expose the underlying source/drain plugs 603, the first etching process may either be stopped without extending into the source/drain plugs 603 or else may be continued to slightly overetch and extend partially into the source/drain plugs 603.

After the first etching process forms the first openings for source/drain contacts 707 a first conductive fill material is deposited to fill the first openings for source/drain contacts 707 to form the source/drain contacts 707. In an embodiment, the first conductive fill material comprises a metal such as tungsten, cobalt (Co), alloys thereof, and the like. Furthermore, the first conductive fill material may be deposited using a deposition process such as a chemical vapor deposition (CVD) However, any suitable conductive fill materials and any suitable processes may be utilized to deposit the source/drain contacts 707. An anneal process or reflow process may be performed after the conductive fill material is deposited to form the source/drain contacts 707.

Once filled or overfilled, any deposited material outside of the first openings for the source/drain contacts 707 may be removed using a planarization process such as chemical mechanical polishing (CMP) to planarize the source/drain contacts 707 with a planarized surface of the second ILD layer 705.

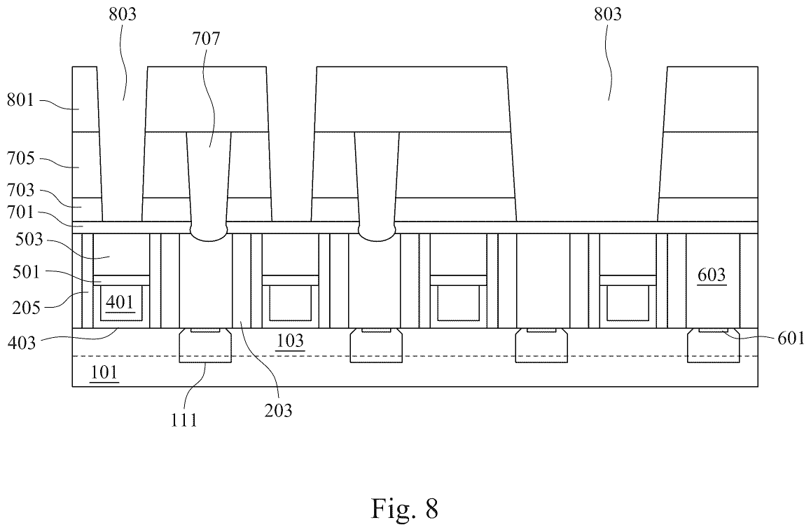

FIG. 8 illustrates the formation of a third ILD 801 formed over the second ILD 705, according to some embodiments. The third ILD 801 may be formed of a dielectric material, and may be deposited by any suitable method, such as CVD, PECVD, or FCVD. Suitable dielectric materials may include PSG, BSG, BPSG, USG, or the like. Other insulation materials formed by any acceptable process may be used. After the third ILD 801 is deposited, a planarization process, such as a CMP, may be performed to planarize a top surface of the third ILD 801.

FIG. 8 further illustrates, according to some embodiments, a formation of second openings 803 through the third ILD 801, the second ILD 705, and the contact etch stop layer 703 down to the first etch stop layer 701. The second openings 803 can be formed using a series of one or more acceptable photolithography and etching techniques. The formation of the third ILD 801 prevents the source/drain contacts 707 from being exposed to the etching process that forms the second openings 803 and thereby helps protect the source/drain contacts 707 from experiencing etch damage during the formation of the second openings 803. According to some embodiments, a second etching process may be performed using precursors such as trifluoromethane (CHF₃) and hydrogen (H₂) to etch through the third ILD 801, the second ILD 705 and punch through the contact etch stop layer 703. However, any suitable etchants, and any suitable number or combination of etching processes, may be utilized, and all such etchants and combinations are fully intended to be included within the scope of the embodiments.

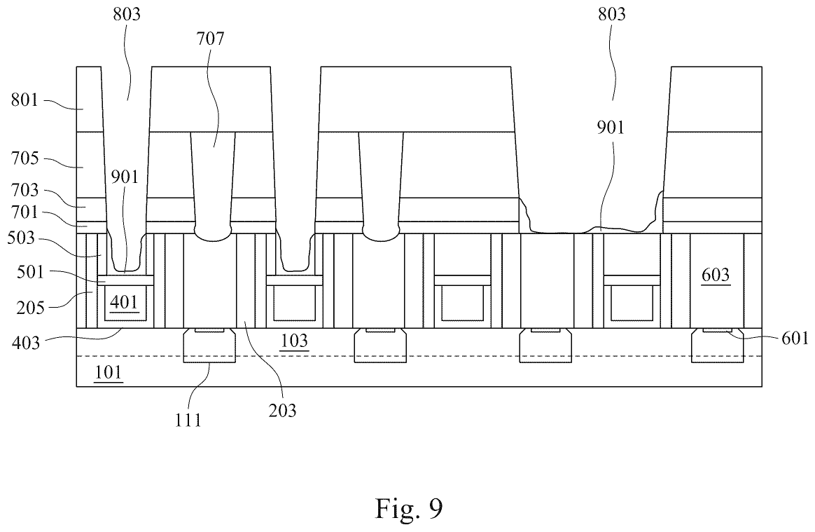

FIG. 9 illustrates, according to some embodiments, a continuation of the second etching process that may be carried out to extend the second openings 803 down to the gate contact layer 501 and/or the source/drain plugs 603. According to some embodiments, the second etching process may be performed using precursors such as carbon tetrafluoride (CF₄) and hydrogen (H₂) to etch through the first etch stop layer 701 and the gate mask 503. However, any suitable etchants, and any suitable number or combination of etching processes, may be utilized, and all such etchants and combinations are fully intended to be included within the scope of the embodiments.

FIG. 9 further illustrates that the second etching process also results in polymeric residues and etch by-products 901 formed on exposed surfaces in the second openings 803, in accordance with some embodiments. These polymeric residues and etch by-products 901 may degrade the quality of the exposed surfaces in the second openings 803. These polymeric residues and etch by-products 901 may result in undesirable effects (e.g. increased contact resistance). Additionally, the exposed surfaces in the second openings 803 with the polymeric residues and etch by-products 901 may be prone to oxidation after a wet or dry cleaning process. Typical polymeric residues and etch by-products 901 may include fluorine (F), carbon (C), tungsten (W), cobalt (Co) and other species in various combinations. For example, various CxFy, WFx, WOx, CoFx, CoxOy, SiFx compounds or polymers may be produced on the exposed surfaces in the second openings 803 by the reaction of etchant gases with the freshly exposed surfaces.

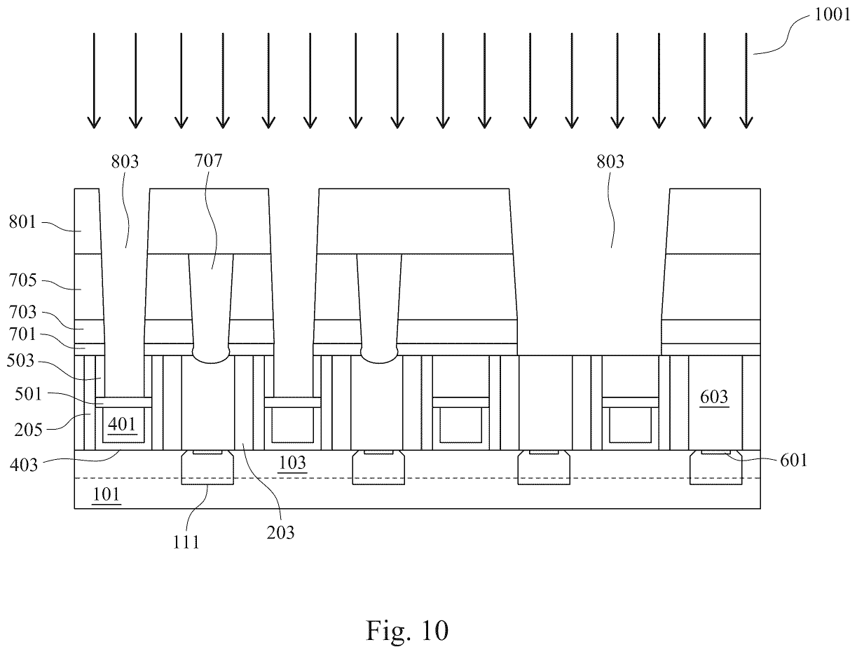

FIG. 10 illustrates a post-etch treatment 1001 to remove the polymeric residues and etch by-products 901 on the exposed surfaces in the second openings 803 carried out in a process chamber (not shown). The post-etch treatment 1001 utilizes a plasma formed from a gas mixture. The gas mixture comprising a first gas, corresponding to a first high energy species in the plasma and a second gas, corresponding to a second high energy species in the plasma.

The first high energy species, once formed into the plasma, is utilized to bombard the polymeric residues and etch by-products 901 on the exposed surfaces of the second openings 803 with controlled ion energy to release reactive species of the polymeric residues and etch by-products from the exposed surfaces of the second openings 803. Some of the released reactive species may diffuse into the exposed surfaces of the second openings 803, such as, for example, some of the released reactive species diffusing into the gate contact layer 501. The released reactive species may also be removed from the semiconductor structure as part of the post-etch treatment 1001. The first gas utilized to form the first high energy species may include diatomic oxygen, argon, diatomic hydrogen, combinations of these, or the like.

The second high energy species, once formed into the plasma, is formed from the second gas. The second high energy species may also be utilized to bombard the polymeric residues and etch by-products 901 on the exposed surfaces of the second openings 803 with controlled ion energy to release reactive species of the polymeric residues and etch by-products from the exposed surfaces of the second openings 803. The released reactive species may then be removed from the semiconductor structure as part of the post-etch treatment 1001. The second gas utilized to form the second high energy species may include diatomic hydrogen, argon, combinations of these, or the like.

The first gas and the second gas may flow separately or pre-mixed into a plasma reactor where the plasma is produced. The plasma reactor may be disposed in a process chamber in which the substrate 101 is disposed, or disposed remotely from the process chamber. The plasma reactor may be any suitable reactor that has separate controls for power input to a plasma source generator and to a substrate bias device. In one implementation, the plasma reactor is an inductively coupled plasma (ICP) reactor. In such a case, the plasma reactor may have a plasma source controller controlling the supply of inductively coupled RF power which determines plasma density (source power), and a bias controller controlling the supply of RF power or DC power which is used to generate a bias voltage on the substrate surface (bias power). The bias voltage can be used to control the bombardment energy of the first high energy species and the second high energy species toward the substrate 101, for example, towards the exposed surfaces of the second openings 803. While the ICP reactor is used in this disclosure as an example for forming the plasma, it is contemplated that other plasma sources, such as a capacitively coupled plasma (CCP) source, a decoupled plasma source (DPS), a magnetron plasma source, an electron cyclotron resonance (ECR) source, or a microwave plasma source, may also be used.

The following process chamber parameters may be used to perform the post-etch treatment 1001. In various implementations, the gas mixture may have a composition range of about 5% first gas and about 95% second gas to about 80% first gas and about 20% second gas, such as about 10% first gas and 90% second gas, the reactor pressure may be about 0.5 Torr to about 3 Torr, for example such as about 1 Torr. The source power may be about 2,000 watts (W) to about 5,000 W, for example, such as about 3,500 W. The process chamber temperature may be about 150° C. to about 250° C., for example such as about 200° C. If the temperature is too low, the reaction rate will be very low. If the temperature is too high, the temperature might damage the process chamber. The gas flow of the gas mixture may be about 8,000 sccm to about 10,000 sccm, for example such as about 9,000 sccm. If the gas flow is too low, the reaction rate will be very low. If the gas flow is too high the plasma species may damage the process chamber, e.g. hydrogen plasma may damage the process chamber (which may in part be made of quartz) if the gas flow is too high. The treatment time may be about 60 seconds to about 180 seconds, for example such as about 120 seconds. In an embodiment where the chamber process parameters are performed at the gas flow of 8,000 sccm for a treatment time of 60 seconds the post-etch treatment 1001 subjects the exposed surfaces in the second openings 803 to 8,000 standard cubic centimeters of the gas mixture. In another embodiment where the chamber process parameters are performed at the gas flow of 10,000 sccm for the treatment time of 180 seconds the post-etch treatment 1001 subjects the exposed surfaces in the second openings 803 to 30,000 standard cubic centimeters of the gas mixture. It is contemplated that these process parameters may vary depending upon the size of the second openings 803, the size of the substrate 101, the capability of the plasma reactor, the application, etc.

In an implementation the post-etch treatment 1001 is performed in a nitrogen free atmosphere, where no additional nitrogen is introduced or present in the atmosphere during the post-etch treatment 1001 as additional nitrogen may impede metal growth carried out in later processing steps. In another implementation the post-etch treatment 1001 is performed in an inert gas free atmosphere, where no additional inert gases, such as argon, are present in the atmosphere during the post-etch treatment 1001.

In an implementation the first high energy species is formed from diatomic oxygen gas and the second high energy species is formed from diatomic hydrogen gas. The high energy oxygen species and high energy hydrogen species then bombard the polymeric residues and etch by-products 901 on the exposed surfaces of the second openings 803 releasing reactive species of the polymeric residues and etch by-products from the exposed surfaces of the second openings 803. In this implementation the gate contact layer may further be comprised of the fluorine-free tungsten and the high energy oxygen species may diffuse into the exposed surface of the gate contact layer 501 and/or react with the tungsten forming WOx compounds in the gate contact layer 501.

Optionally, once the post-etch treatment 1001 has been performed, the substrate 101 may be subjected to a cleaning process. In an embodiment the cleaning process may be a wet cleaning process to help facilitate the removal of any remaining parts of the polymeric residues and etch by-products 901. For example, the wet cleaning process may be a distilled water rinse process. However, any suitable cleaning process may be utilized.

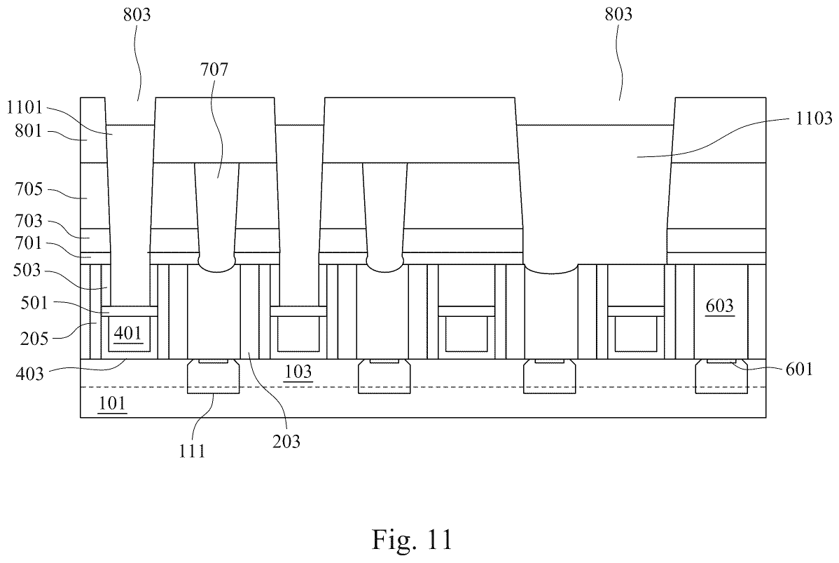

FIG. 11 illustrates the development of subsequent structures within the second openings 803 following the post-etch treatment 1001. Specifically, the figure illustrates the formation of gate electrode contacts 1101 and butted contact 1103. Accordingly, a second conductive fill material is deposited to fill the second openings 803. The second conductive fill material may be a metal, such as tungsten, cobalt, copper, ruthenium, aluminum. Furthermore, the conductive fill material may be deposited using a deposition process such as a chemical vapor deposition (CVD) to perform a bottom-up selective loss free deposition. The second conductive fill material deposited to fill the second openings 803 can produce gate electrode contacts 1101 with a growth height ranging between about 2.01 nm to about 39.82 nm, such as, for example 34.05 nm. In a bottom-up deposition, precursors are specifically selected so that during the deposition process the conductive fill material will have a single growth front that propagates vertically in the second openings 803; as such, seams are prevented from forming in the conductive fill material. However, any suitable conductive fill materials and any suitable processes may be utilized to develop the gate electrode contacts 1101 and butted contact 1103 within the second openings 803.

In an embodiment the deposition process may utilize precursors such as tungsten fluoride (WF₆) and hydrogen (H₂), although any suitable precursors such as W(CO)₆, (NH₃)₃W(CO)₃, WCl₅, C₁₀H₁₂W, WH₂(iPrCp)₂, the like, or a combination thereof, may be utilized. In a particular embodiment using tungsten fluoride and hydrogen as the precursors, the tungsten fluoride (WF₆) may be flowed into a reaction chamber at a flow rate of between about 50 sccm and about 450 sccm, such as about 100 sccm, while the hydrogen (H₂) may be flowed in at the same time at a flow rate of between about 1,000 sccm and about 7,000 sccm, such as about 2000 sccm. Additionally, the chemical vapor deposition process may be performed at a temperature of between about 200° C. and about 400° C., such as about 300° C., and at a pressure of between about 10 torr and about 300 torr, such as about 20 torr.

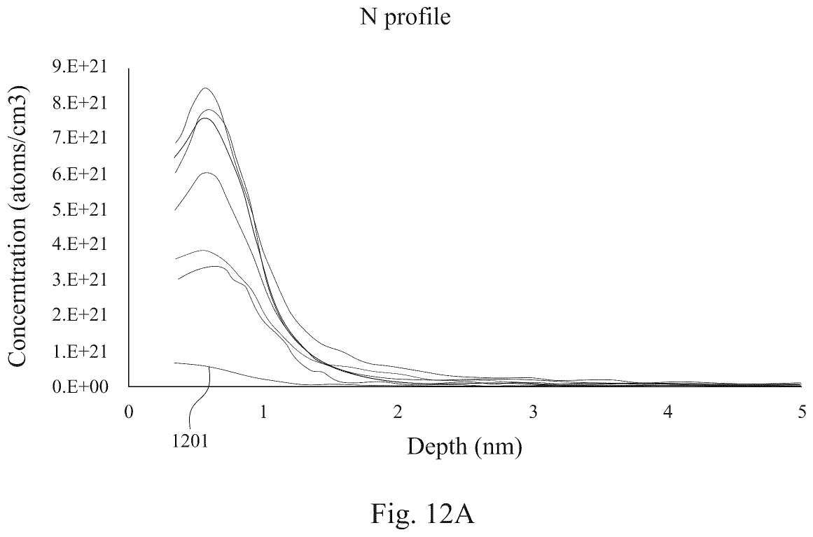

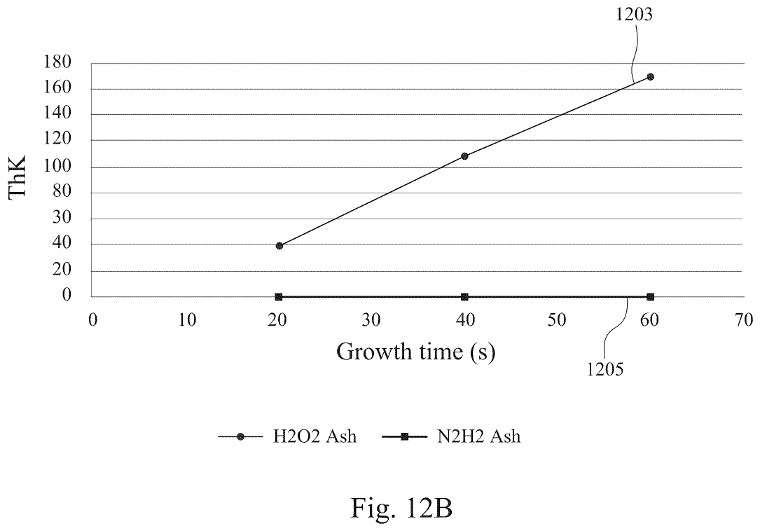

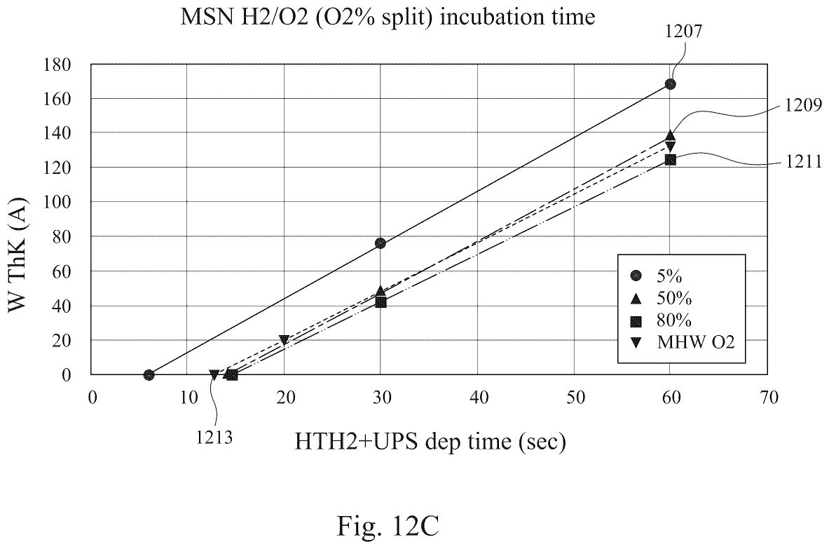

Further, in an implementation where the gate electrode contacts 1101 are formed utilizing the bottom-up deposition process to deposit the second conductive fill material onto the exposed surface of the gate contact layer 501 in the second openings 803, the deposition of the gate electrode contacts 1101 can be performed with less interference from the presence of nitrogen, since nitrogen is not utilized in the post-etch treatment 1001. For example, as illustrated in FIG. 12A, when the post-etch treatment 1001 is utilized as described, a reduced nitrogen profile in the gate contact layer 501 is present following the formation of the gate electrode contacts 1101. In an embodiment where the first gas comprises diatomic oxygen gas and the second gas comprises diatomic hydrogen gas and the post-etch treatment 1001 occurs in a nitrogen free atmosphere the nitrogen concentration present at a surface of the gate contact layer 501 following the bottom-up deposition process (represented by the line labeled 1201) is lower than other processes. In a particular embodiment, the nitrogen concentration is greater than 0 atoms per cubic centimeter and less than about 1E+21 atoms per cubic centimeter at a surface of the gate contact layer 501.

FIG. 12B illustrates a chart of gate electrode contact thickness on the gate contact layer 501 during the bottom-up deposition process, where the growth height is shown as occurring after a shortened incubation time resulting from the post-etch treatment 1001. In an embodiment where the post-etch treatment 1001 utilizes oxygen and hydrogen and where the gate contact layer 501 comprises FFW and the second conductive fill material comprises tungsten (represented in the figure by the line labeled 1203), the growth height of the gate electrode contact 1101 is at least 4 nm (the growth heights represented in the figure are in angstroms) after a growth time ranging between about 20 seconds and 60 seconds (as compared to the about 2.6 nm growth height if nitrogen is utilized, represented in the figure by the line labeled 1205).

FIG. 12C illustrates a chart of the gate electrode contact 1101 thickness on the gate contact layer 501 during the bottom-up deposition process, where the growth height and incubation time delay can be chosen by choosing a ratio of the first gas to the second gas in the gas mixture utilized to form the plasma for the post-etch treatment 1001. In an embodiment where the gas mixture used to form the plasma is about 5% oxygen and about 95% hydrogen the resulting incubation time delay is about 6.0 seconds represented in the figure by line 1207. In another embodiment where the gas mixture used to form the plasma is about 50% oxygen and about 50% hydrogen the resulting incubation time delay is about 14.2 seconds represented in the figure by line 1209. In another embodiment where the gas mixture used to form the plasma is about 80% oxygen and about 20% hydrogen the resulting incubation time delay is about 14.7 seconds represented in the figure by line 1211. In an another embodiment where the gas mixture used to form the plasma is 100% oxygen the resulting incubation time delay is about 12.8 seconds represented in the figure by line 1213.

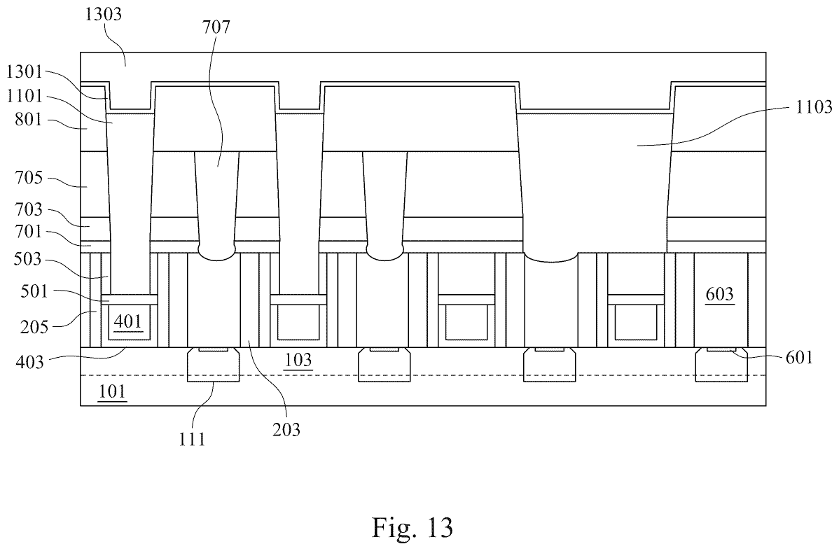

FIG. 13 illustrates an embodiment where following the formation of gate electrode contacts 1101 and butted contact 1103 a barrier layer 1301 is deposited over the remaining exposed surfaces in the second openings 803. In one implementation the barrier layer 1301 comprises titanium or titanium nitride and may be deposited by CVD. However, any suitable materials and any suitable processes may be utilized to deposit the barrier layer 1301. Following the deposition of the barrier layer 1301 a plug 1303 may be formed over the barrier layer 1301 and over the third ILD 801. The plug 1303 helps provide stability in the substrate 101 during subsequent planarization processing (discussed in greater detail with respect to FIG. 13) by minimizing the variation across materials being planarized, thereby reducing the degradation to the substrate 101 that can occur otherwise during such planarization processes. In an implementation the plug 1303 is formed from the same material as the gate electrode contacts (i.e. tungsten). In one implementation the plug 1303 comprises tungsten and may be deposited by CVD. However, any suitable materials and any suitable processes may be utilized to deposit the plug 1303.

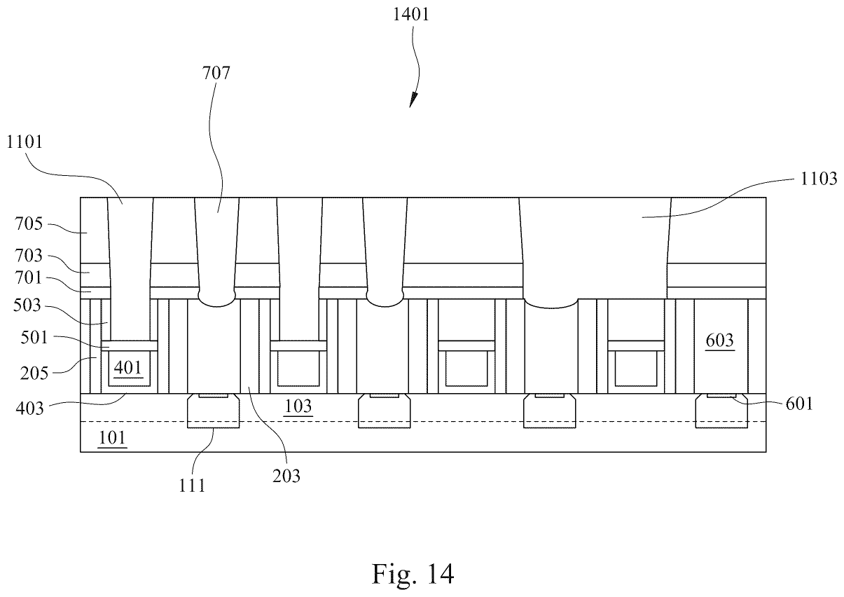

FIG. 14 illustrates that, following the formation of gate electrode contacts 1101 and butted contact 1103, the substrate 101 is subjected to a planarization process 1401 such as CMP in order to expose a top surface of the source/drain contacts 707. The planarization process 1401 removes the third ILD 801 to expose the top surface of the source/drain contacts, along with a portion of gate electrode contacts 1101 and butted contact 1103. The result of planarization process 1401 is a top planar surface in which source/drain contacts 707, gate electrode contacts 1101 and butted contact 1103 have an exposed conductive surface on the top planar surface. The planarization process 1401 allows for the development of additional features capable of coupling the conductive features within intermediate structure 100 as well as providing access points from which to process external connectors to interface with the substrate 101.

Embodiments disclosed herein may achieve advantages. For example, the post-etch treatment 1001 is able to assist in the removal of the polymeric residues and etch by-products 901 formed on exposed surfaces in the second openings 803 while maintaining a nitrogen profile at the surface of gate contact layer 501 of less than about 1E+21 nitrogen atoms per cubic centimeter at the surface of gate contact layer 501 following the bottom-up deposition process. As such the formation of the gate electrode contacts 1101 may be formed by the bottom-up deposition process onto the gate contact layer 501 so that seams may be prevented from forming within the second conductive fill material during the formation of the gate electrode contacts 1101 with improved growth heights, such as over 4 nm after 20 seconds of growth time and reduced incubation time delays, such as about 5.95 seconds, when compared to previous post-etch treatments utilizing nitrogen which may result in growth heights of less than 2.63 nm after growth times over 180 seconds.

In an accordance with an embodiment, a method of manufacturing a semiconductor device includes: forming a gate contact layer over a gate electrode, the gate electrode over a channel region of a semiconductor material; forming an etch stop layer over the gate contact layer; forming a dielectric layer over the etch stop layer; performing an etching process to form a first opening, wherein the first opening extends through the dielectric layer and the etch stop layer to expose the gate contact layer; performing a post etching treatment wherein the post etching treatment includes forming a plasma comprising oxygen and hydrogen, wherein the plasma does not include nitrogen; and after the performing the post etching treatment, performing a bottom-up deposition process to fill the first opening. In an embodiment, the bottom-up deposition process deposits tungsten. In an embodiment, the plasma further does not include an inert gas. In an embodiment, a growth height in the first opening from the bottom-up deposition process is greater than 4 nm after the growth time of about 20 seconds. In an embodiment, the gate contact layer includes fluorine-free tungsten. In an embodiment, the plasma is formed from a gas mixture comprising 95% hydrogen gas and 5% oxygen gas. In an embodiment, the bottom-up deposition process has an incubation time delay ranging from about 6.0 seconds to about 14.7 seconds.

In accordance with another embodiment, a method of manufacturing a semiconductor device includes: forming a gate stack; forming a mask layer over the gate stack, wherein the mask layer comprises fluorine-free tungsten; forming a dielectric layer over the mask layer; forming a gate stack via opening exposing the mask layer through the dielectric layer, wherein the forming the gate stack via opening produces etch by-products in the gate stack via opening; cleaning the etch by-products by exposing the gate stack via opening to a plasma comprising a first high energy species and hydrogen; and performing a bottom-up deposition process in the gate stack via opening by initializing a growth of a conductive via material on the mask layer. In an embodiment, the first high energy species includes oxygen. In an embodiment, the first high energy species includes argon. In an embodiment, after the cleaning the mask layer includes between 0 and 1E+21 nitrogen atoms per cubic centimeter. In an embodiment, during the cleaning a total volume of hydrogen and oxygen exposed to the gate stack via opening is between about 8,000 cubic centimeters to about 30,000 cubic centimeters. In an embodiment, after the cleaning the mask layer includes tungsten oxide compounds. In an embodiment, the method further includes, following the cleaning, rinsing the gate stack via opening.

In accordance with yet another embodiment, a semiconductor device includes: a gate electrode comprising a gate portion and a gate contact layer, wherein the gate contact layer has a nitrogen concentration greater than 0 atoms per cubic centimeter and less than about 1E+21 atoms per cubic centimeter; a dielectric layer over the gate electrode; and a gate electrode plug extending through the dielectric layer and interfacing with the gate electrode. In an embodiment, the gate electrode plug includes tungsten. In an embodiment, the semiconductor device further includes a source/drain plug, wherein the source/drain plug comprises cobalt. In an embodiment, the semiconductor device further includes a source/drain plug with a first height, wherein the gate electrode has a second height, and wherein the first height is greater than the second height. In an embodiment, the gate contact layer comprises fluorine-free tungsten. In an embodiment, the gate contact layer comprises tungsten oxide compounds.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device comprising:
a gate electrode comprising a gate portion and a gate contact layer, wherein the gate contact layer has a nitrogen concentration greater than o atoms per cubic centimeter and less than about 1E+21 atoms per cubic centimeter;
a dielectric layer over the gate electrode; and
a gate electrode plug extending through the dielectric layer and interfacing with the gate electrode.

2. The semiconductor device of claim 1, wherein the gate electrode plug comprises tungsten.

3. The semiconductor device of claim 2, further comprising a source/drain plug, wherein the source/drain plug comprises cobalt.

4. The semiconductor device of claim 1, further comprising a source/drain plug with a first height, wherein the gate electrode has a second height, and wherein the first height is greater than the second height.

5. The semiconductor device of claim 1, wherein the gate contact layer comprises fluorine-free tungsten.

6. The semiconductor device of claim 1, wherein the gate contact layer comprises tungsten oxide compounds.

7. The semiconductor device of claim 1, wherein the gate electrode plug comprises tungsten.

8. A semiconductor device comprising:
a gate electrode;
a gate contact layer over the gate electrode;
a dielectric layer over the gate contact layer; and
a gate contact extending through the dielectric layer to the gate contact layer, wherein the gate contact layer has a nitrogen concentration greater than o atoms per cubic centimeter and less than about 1E+21 atoms per cubic centimeter at an interface between the gate contact layer and the gate contact.

9. The semiconductor device of claim 8, wherein the gate contact layer comprises tungsten.

10. The semiconductor device of claim 9, wherein the gate contact layer comprises fluorine-free tungsten.

11. The semiconductor device of claim 9, wherein the gate contact comprises tungsten.

12. The semiconductor device of claim 8, wherein the gate contact layer comprises tungsten oxide compounds.

13. The semiconductor device of claim 8, wherein the gate contact is a butted contact in electrical contact with the gate contact layer and a source/drain plug.

14. The semiconductor device of claim 13, wherein the butted contact extends into the source/drain plug more than the butted contact extends into the gate contact layer.

15. A semiconductor device comprising:
a metal feature;
a dielectric layer over the metal feature; and
a first contact extending through the dielectric layer to the metal feature, wherein the metal feature has a nitrogen concentration greater than o atoms per cubic centimeter and less than about 1E+21 atoms per cubic centimeter at a surface of the metal feature, the surface of the metal feature facing the first contact.

16. The semiconductor device of claim 15, wherein the metal feature is part of a gate electrode structure.

17. The semiconductor device of claim 15, wherein the metal feature and the first contact comprise tungsten.

18. The semiconductor device of claim 15, wherein the metal feature comprises fluorine-free tungsten.

19. The semiconductor device of claim 15, further comprising a second contact extending through the dielectric layer, wherein the second contact comprises cobalt.

20. The semiconductor device of claim 19, wherein a height of the first contact is greater than a height of the second contact.
